(19) United States
(12) Patent Application Publication
(10) Pub. No.: US 2026/0195492 A1
(43) Pub. Date: Jul. 9, 2026

(54) GENERATING PANEL LAYOUTS FOR BUILDING FACADES

(71) Applicant: Signetron Inc., Berkeley, CA (US)

(72) Inventors: Avideh Zakhor, Berkeley, CA (US); Lauren Go, San Francisco, CA (US); Jason Zou, Oakland, CA (US)

(21) Appl. No.: 19/012,663

(22) Filed: Jan. 7, 2025

(51) Int. Cl. G06F 30/13; G06F 30/12

(52) U.S. Cl. CPC G06F 30/13; G06F 30/12

(57) ABSTRACT

Methods for generating panel layouts for building facades are presented including: receiving a 2D facade polygon, where the 2D facade polygon represents an outline of a building facade; receiving a set of 2D fenestration polygons, where the set of 2D fenestration polygons represent a number of window outlines and a number of door outlines corresponding with the building facade; and determining a panel layout for the building facade. In some embodiments, the determining a panel layout for the building facade includes: inputting layout parameters; performing a first guillotine operation to initially divide the building facade into horizontal strips defined by a number of horizontal cuts; creating the panel layout selected from the group consisting of: a window enclosed layout, a window aligned layout, a window crossing (MID) layout, and a window crossing (ANY) layout; and optionally returning to the inputting layout parameters.

### BACKGROUND

Recladding projects, which involve completely covering the exterior of a building with insulation panels to improve its energy efficiency, require architects to design panel layouts for each of a building's facades. Coming up with these layouts is not always straightforward, as there are aesthetic preferences and physical constraints to consider, like the locations of windows and doors on the facade, the desire for a near-symmetrical layout, and limits on the sizes of panels that can be manufactured. The ability to rapidly generate several different layouts for a particular building facade, as well as the ability to refine layouts quickly and easily by experimenting with different input parameters, would allow a user to consider a wider variety of layout options and more easily find the one that's most suitable for a project.

As such, methods for generating panel layouts for building facades are presented herein.

### SUMMARY

The following presents a simplified summary of some embodiments of the invention in order to provide a basic understanding of the invention. This summary is not an extensive overview of the invention. It is not intended to identify key/critical elements of the invention or to delineate the scope of the invention. Its sole purpose is to present some embodiments of the invention in a simplified form as a prelude to the more detailed description that is presented below.

As such, methods for generating panel layouts for building facades are presented including: receiving a 2D facade polygon, where the 2D facade polygon represents an outline of a building facade; receiving a set of 2D fenestration polygons, where the set of 2D fenestration polygons represent a number of window outlines and a number of door outlines corresponding with the building facade; and determining a panel layout for the building facade. In some embodiments, the determining a panel layout for the building facade includes: inputting layout parameters; performing a first guillotine operation to initially divide the building facade into horizontal strips defined by a number of horizontal cuts; creating the panel layout selected from the group consisting of: a window enclosed layout, a window aligned layout, a window crossing (MID) layout, and a window crossing (ANY) layout; and optionally returning to the inputting layout parameters. In some embodiments, the guillotine operation includes: calculating an ideal panel size for the building facade; finding one or more zones free of conflict (ZOFCOS); placing a number of cuts to divide the one or more ZOFCOS; adjusting the number of cuts to new cut positions in accordance with the layout parameters and the ideal panel size; and continuing the adjusting the number of cuts until the new cut positions do not change. In some embodiments, methods include: optionally removing one of the number of cuts to merge neighboring regions separated by the one of the number of cuts in accordance with the layout parameters. In some embodiments, the layout parameters include: a minimum acceptable width of a panel; a maximum acceptable width of a panel; a minimum acceptable height of a panel; a maximum acceptable height of a panel; a minimum acceptable margin between a window edge and a panel edge; a real number whose value represents a position of a horizontal support line. In some embodiments, the creating the window enclosed layout includes: performing a second guillotine operation to initially divide the building facade into vertical strips defined by a number of vertical cuts, where the layout parameters further include a selectively enforced Delta parameter, the selectively enforced Delta parameter defining the minimum acceptable margin between a window edge and a panel edge; intersecting the number of horizontal cuts and the number of vertical cuts; and displaying the window enclosed layout. In some embodiments, if a space between a pair of window or door cutouts is less than the selectively enforced Delta parameter, ignoring the selectively enforced Delta parameter; or merging each pair of window or door cutouts with the space between the pair of window or door cutouts into a single merged cutout. In some embodiments, the creating the window aligned layout includes: for a first horizontal strip having a door or a window, creating a number of vertical cuts at vertical edges of the number of window outlines and the number of door outlines, where the number of horizontal cuts and the number of vertical cuts define a number of panel regions; dividing any panel region that is greater than the maximum acceptable width of a panel; for a second horizontal strip not having a door or window, inheriting the number of vertical cuts from a nearest horizontal strip having the door or the window; and displaying the window aligned layout. In some embodiments, the creating the window crossing (MID) layout includes: for a first horizontal strip having a door or a window, creating a number of vertical cuts at midpoints of the number of window outlines and the number of door outlines, where the number of horizontal cuts and the number of vertical cuts define a number of panel regions; dividing any panel region that is greater than the maximum acceptable width of a panel; for a second horizontal strip not having a door or window, inheriting the number of vertical cuts from a nearest horizontal strip having the door or the window; and displaying the window crossing (MID) layout. In some embodiments, the creating the window crossing (ANY) layout includes: for a first horizontal strip having a window, creating a number of vertical cuts at midpoints of closest pairs of neighboring windows; further dividing the first horizontal strip having the window to a user selected width; adjusting any vertical cut of any panel region that is less than the minimum acceptable width of a panel; adjusting any vertical cut of any panel region that is greater than the maximum acceptable width of a panel; dividing a rightmost panel region that is greater than the maximum acceptable width of the panel; and displaying the window crossing (ANY) layout. In some embodiments, the set of 2D fenestration polygons is empty.

The features and advantages described in the specification are not all inclusive and, in particular, many additional features and advantages will be apparent to one of ordinary skill in the art in view of the Drawings, Specification, and Claims. Moreover, it should be noted that the language used in the specification has been principally selected for readability and instructional purposes and may not have been selected to delineate or circumscribe the inventive subject matter.

### BRIEF DESCRIPTION OF THE DRAWINGS

The present invention is illustrated by way of example, and not by way of limitation, in the figures of the accompanying drawings in which like reference numerals refer to similar elements and in which:

FIG. 1 is an illustrative flowchart of methods for generating panel layouts for building facades in accordance with embodiments of the present invention;

FIG. 2 is an illustrative flowchart of panel layout selection in accordance with embodiments of the present invention;

FIG. 3 is an illustrative flowchart of methods of performing guillotine operations used in generating panel layouts for building facades in accordance with embodiments of the present invention;

FIG. 4 are illustrative representations of facade regions delineated by guillotine operations in accordance with embodiments of the present invention;

FIG. 5 is an illustrative flowchart of window enclosed variant methods for generating panel layouts for building facades in accordance with embodiments of the present invention;

FIG. 6 is an illustrative flowchart of window aligned variant methods for generating panel layouts for building facades in accordance with embodiments of the present invention;

FIG. 7 is an illustrative flowchart of window crossing (MID) sub-variant methods for generating panel layouts for building facades in accordance with embodiments of the present invention;

FIG. 8 is an illustrative flowchart of window crossing (ANY) sub-variant methods for generating panel layouts for building facades in accordance with embodiments of the present invention;

FIG. 9 is an illustrative representation of a window enclosed variant panel layout for a building facade in accordance with embodiments of the present invention;

FIG. 10 is an illustrative representation of a window aligned variant panel layout for a building facade in accordance with embodiments of the present invention;

FIG. 11 is an illustrative representation of a window crossing (MID) sub-variant panel layout for a building facade in accordance with embodiments of the present invention;

FIG. 12 is an illustrative representation of a window crossing (ANY) sub-variant panel layout for a building facade in accordance with embodiments of the present invention;

FIG. 13 is an illustrative representation of a pair of facades that have a conflict in accordance with embodiments of the present invention; and

FIG. 14 is an illustrative flowchart of methods of finding conflicts in wireframe building models in accordance with embodiments of the present invention.

### DETAILED DESCRIPTION

The present invention will now be described in detail with reference to a few embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to not unnecessarily obscure the present invention.

As will be appreciated by one skilled in the art, the present invention may be a system, a method, and/or a computer program product. The computer program product may include a computer readable storage medium (or media) having computer readable program instructions thereon for causing a processor to carry out aspects of the present invention. The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing.

A computer readable storage medium, as used herein, is not to be construed as being transitory signals /per se/, such as radio waves or other freely propagating electromagnetic waves, electromagnetic waves propagating through a waveguide or other transmission media (e.g., light pulses passing through a fiber-optic cable), or electrical signals transmitted through a wire. Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device. Computer readable program instructions for carrying out operations of the present invention may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions. These computer readable program instructions may be provided to a processor of a general-purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks. The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks. The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The computer program instructions may also be loaded onto a computer or other programmable data processing apparatus to cause a series of operational steps to be performed on the computer or other programmable apparatus to produce a computer implemented process such that the instructions which execute on the computer or other programmable apparatus provide processes for implementing the functions/acts specified in the flowchart and/or block diagram block or blocks.

In still other instances, specific numeric references such as “first material,” may be made. However, the specific numeric reference should not be interpreted as a literal sequential order but rather interpreted that the “first material” is different than a “second material.” Thus, the specific details set forth are merely exemplary. The specific details may be varied from and still be contemplated to be within the spirit and scope of the present disclosure. The term “coupled” is defined as meaning connected either directly to the component or indirectly to the component through another component. Further, as used herein, the terms “about,” “approximately,” or “substantially” for any numerical values or ranges indicate a suitable dimensional tolerance that allows the part or collection of components to function for its intended purpose as described herein.

Methods disclosed herein provide optimal panel layouts for a facade given a variety of practical constraints as noted above. At the core of these methods is the ability to draw “cuts” both horizontally and vertically across a given facade and then intersect these cuts to form a panel layout. Since cutouts need to be made in the panels to accommodate the facade's windows and doors, methods can then further intersect any of the simple rectangular panel outlines in this layout with facade boundaries or window or door outlines to further refine its shape.

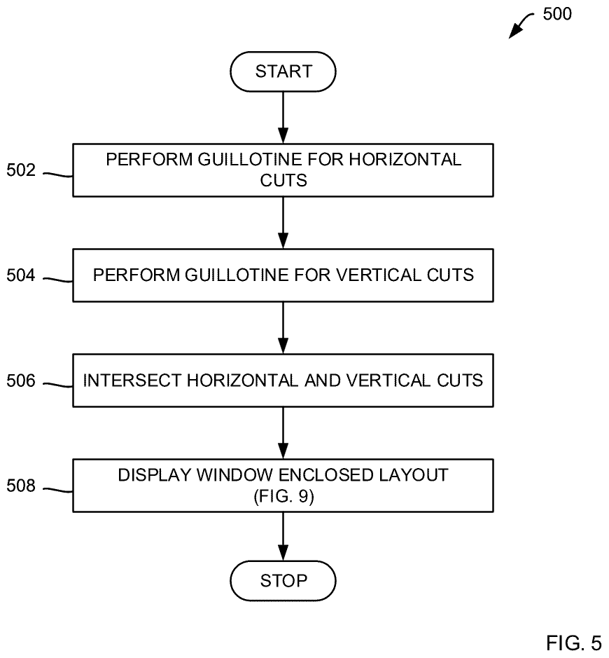

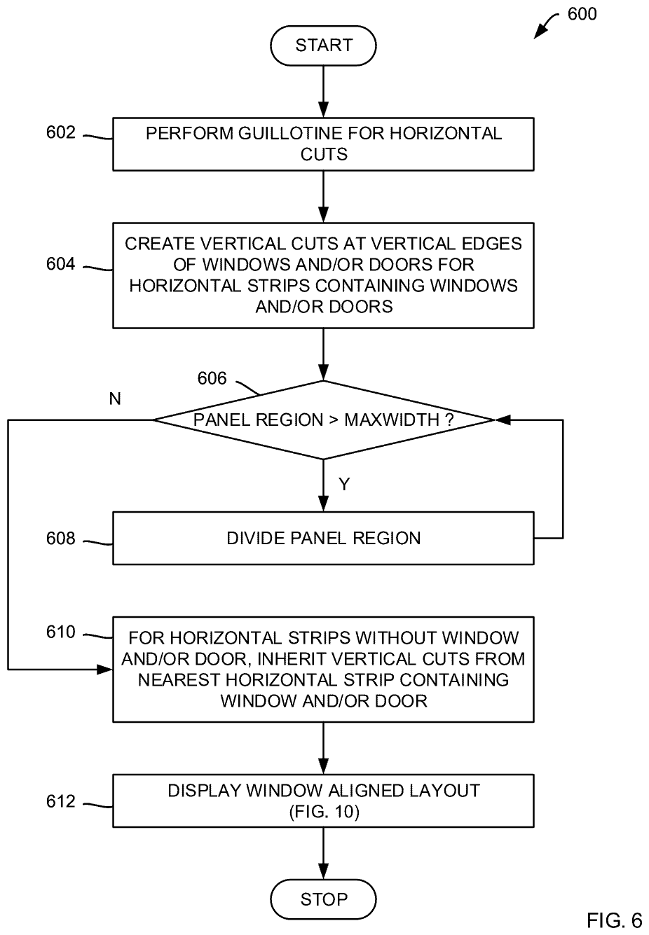

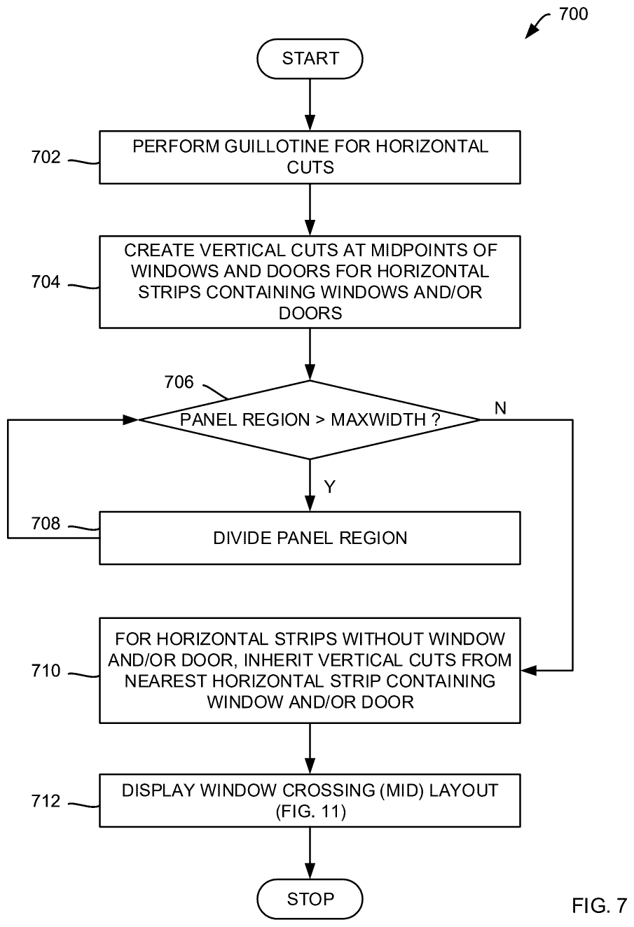

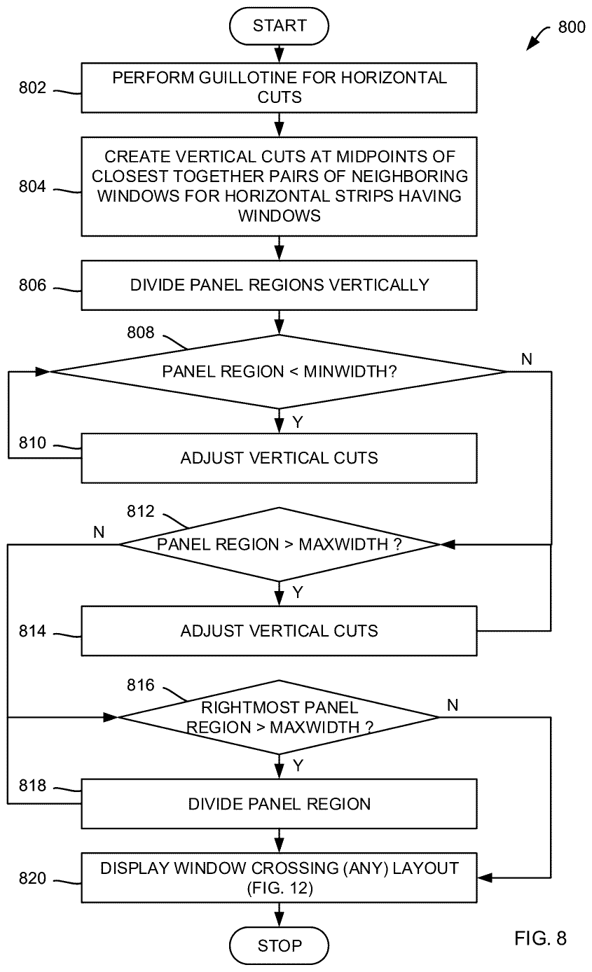

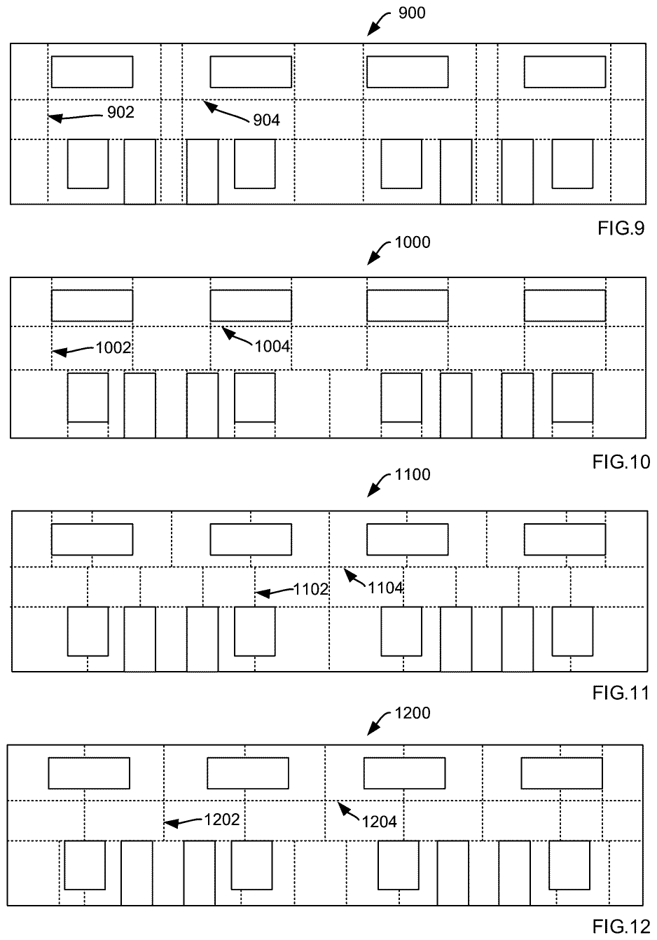

Although simply drawing and intersecting horizontal and vertical cuts will produce a panel layout for any facade, they do not account for different aesthetic preferences and physical or manufacturing constraints. For this reason, methods can perform at least three different variants of the panel layout generation operations, namely a window enclosed variant, a window aligned variant, and a window crossing variant. The window crossing variant includes two sub-variants:
window crossing (MID) and window crossing (ANY), which will be discussed in further detail below. Each variant produces panel layouts with a different look and configuration. Specifically, the positions of window and door cutouts relative to panel boundaries are different in the layouts generated by each variant. In layouts produced by the window enclosed variant, each window or door on the facade is enclosed inside a single panel, and if possible, has even vertical and horizontal padding around it. Window enclosed variants will be discussed in further detail below for FIGS. 5 and 9. In layouts produced by the window aligned variant, each window or door is similarly enclosed inside a single panel, but one of the window or door's edges is precisely aligned with one of the panel's boundaries. Window aligned variants will be discussed in further detail below for FIGS. 6 and 10. In layouts produced by the window crossing variant, cuts can bisect windows and doors vertically, so that each window or door is “framed” by two adjacent panels. Since the point at which cuts bisect the windows or doors plays a role in aesthetics, this variant consists of two sub-variants. In layouts produced by the window crossing (MID) sub-variant, cuts only bisect windows at their midpoints. Window crossing (MID) sub-variants will be discussed in further detail below for FIGS. 7 and 11. In layouts produced by the window crossing (ANY) sub-variant, a soft preference for bisections at the midpoint is enforced but minimizing the number of different panel sizes used in the layout to reduce manufacturing costs is prioritized. Window crossing (ANY) sub-variants will be discussed in further detail below for FIGS. 8 and 12.

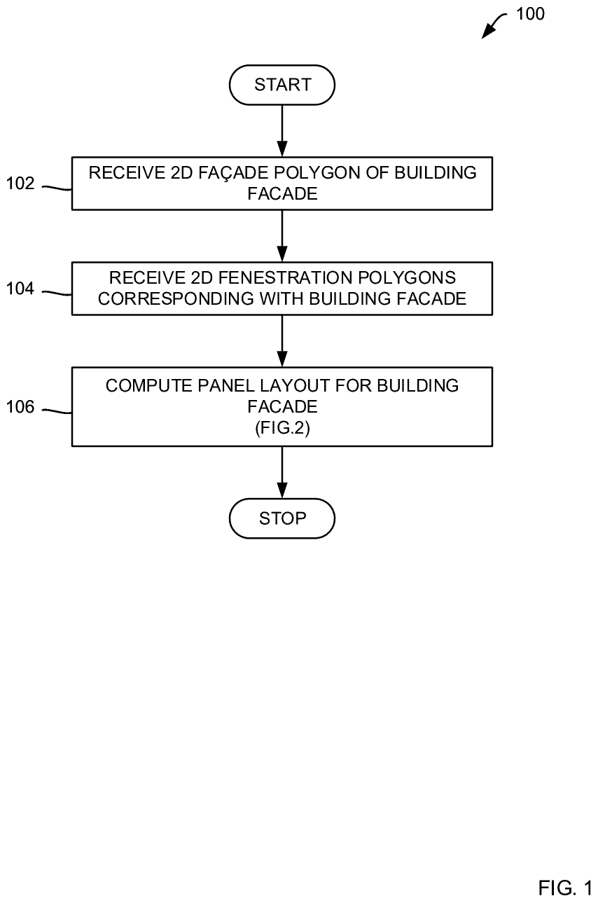

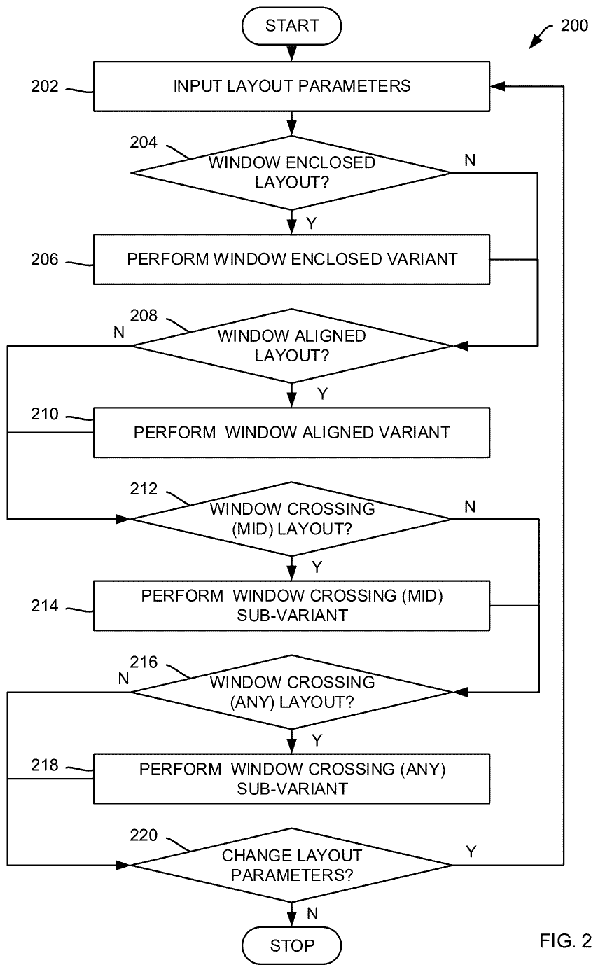

FIG. 1 is an illustrative flowchart 100 of methods for generating panel layouts for building facades in accordance with embodiments of the present invention. At a first step 102, the method receives a 2D facade polygon that represents an outline of a building facade. Typically, building models are created by first using a 3D laser scanner to capture a point cloud of the building and then using scan-to-BIM software to develop the building model based on the point cloud. Building facades may be selected from the building model, whereupon 2D facade polygons are generated that represent the building facades. At a step 104, the method receives a set of 2D fenestration polygons. The 2D fenestration polygons represent outlines of windows and doors corresponding with the building facade. Cutouts must be made in the panels to accommodate these windows and doors. In some embodiments, the set of 2D fenestration polygons is empty - that is, when there are no windows or doors on the building facade. At a next step 106, the method generates panel layouts for the building facade; this step will be discussed in further detail below for FIG. 2.

FIG. 2 is an illustrative flowchart 200 of panel layout selection in accordance with embodiments of the present invention. In particular, FIG. 2 illustrates methods for selecting various layout variants in accordance with embodiments of the present invention. At a first step 202, the method accepts a set of layout parameters. In operation, a user can adjust a number of different parameters so that methods account for certain limitations on the kinds of panels that can be manufactured or used for a particular project. These layout parameters may include, but are not limited to:
MinWidth—a minimum acceptable width of a panel;
MaxWidth—a maximum acceptable width of a panel;
MinHeight—a minimum acceptable height of a panel;
MaxHeight—a maximum acceptable height of a panel;
Delta*—a minimum acceptable margin between a window edge and a panel edge; and
H—(optional) a real number whose value represents a position of a horizontal support line at y=H. In embodiments, multiple such support lines may be specified.
* In the window enclosed variant, if the amount of space between a window or door edge and a facade edge is less than the value of Delta as provided by the user, the method will raise an error. The user can then optionally require the method to automatically ignore the Delta constraint in places where it's physically impossible for the constraint to be satisfied. In addition, if the spacing between a pair of windows or doors is less than the provided value of Delta, the user can again optionally require the method to automatically ignore the Delta constraint when there isn't enough space available to enforce it, but can also have the method automatically merge each pair or cluster of window or door cutouts with less-than-Delta space between them into a single large cutout that the method needs to work around.

At a step 204, the method determines whether to perform a window enclosed variant of the panel layout generation methods. If the method determines at a step 204 to perform a window enclosed variant, the method continues to a step 206 to perform a window enclosed variant, which will be discussed in further detail below for FIGS. 5 and 9. If the method determines at a step 204 not to perform a window enclosed variant, the method continues to a step 208 to determine whether to perform a window aligned variant of the panel layout generation methods. If the method determines at a step 208 to perform a window aligned variant, the method continues to a step 210 to perform a window aligned variant, which will be discussed in further detail below for FIGS. 6 and 10. If the method determines at a step 208 not to perform a window aligned variant, the method continues to a step 212 to determine whether to perform a window crossing (MID) sub-variant of the panel layout generation methods. If the method determines at a step 212 to perform a window crossing (MID) sub-variant, the method continues to a step 214 to perform a window crossing (MID) sub-variant, which will be discussed in further detail below for FIGS. 7 and 11. If the method determines at a step 212 not to perform a window crossing (MID) sub-variant, the method continues to a step 216 to determine whether to perform a window crossing (ANY) sub-variant of the panel layout generation methods. If the method determines at a step 216 to perform a window crossing (ANY) sub-variant, the method continues to a step 218 to perform a window crossing (ANY) sub-variant, which will be discussed in further detail below for FIGS. 8 and 12. If the method determines at a step 216 not to perform a window crossing (ANY) sub-variant, the method continues to a step 220 to determine whether to prompt the user to change the layout parameters. If the method determines at a step 220 to prompt the user to change the layout parameters, the method returns to a step 202 to accept layout parameters. If the method determines at a step 220 not to prompt the user to change the layout parameters, the method ends.

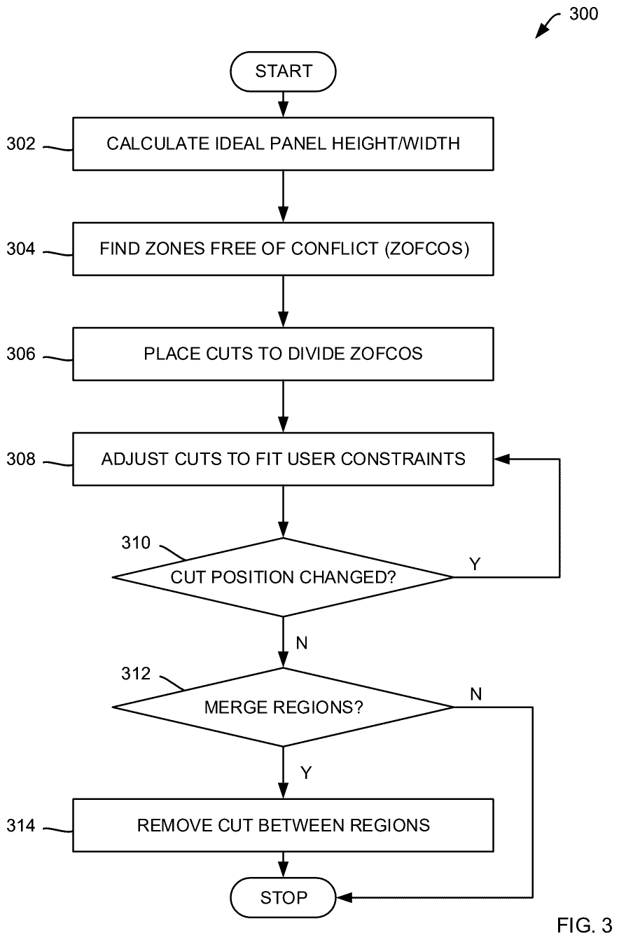

FIG. 3 is an illustrative flowchart 300 of methods of performing guillotine operations used in generating panel layouts for building facades in accordance with embodiments of the present invention. In embodiments, guillotine operations are performed to create horizontal cuts in all three variants of the panel layout generation methods. In addition, the window enclosed variant also performs a guillotine operation to create vertical cuts across entire facades. As such, at a first step 302, the method calculates an ideal panel size for the building facade. Each variant of the layout generation methods must determine where to make cuts in order to divide a particular facade evenly into multiple sub-regions of a uniform size. In embodiments, the minimum number of cuts (N) needed to subdivide a region of size(S) into sub-regions of maximum size (MaxDim) may be calculated as follows:

$$N = ⌈ S / Max Dim ⌉ \qquad ( 1 )$$

In embodiments, the average size (dim) of those sub-regions may then be calculated as follows:

$$dim = S / N \qquad ( 2 )$$

Using the above; (S) is set to either the height of the facade (if creating horizontal cuts) or the width of the facade (if creating vertical cuts), and MaxDim is similarly set to either MaxWidth or MaxHeight.

At a next step 304, the method finds all of the zones free of conflict (ZOFCOS) on the facade. As utilized herein, ZOFCOS are regions along either the vertical axis (if creating horizontal cuts) or the horizontal axis (if creating vertical cuts) in which a line can be drawn through the facade without running into a window or door. If Delta is non-zero, the ZOFCOS are shrunk so that the margin between their endpoints and the window and door edges is Delta. If the amount of space around a window or door is less than the value of Delta provided by the user, and the user has opted to have the method automatically ignore the Delta constraint when there isn't enough space available to enforce it, then the associated ZOFCOS are still shrunk to the extent physically possible. At a step 306, the method places cuts across the facade to divide the ZOFCOS into smaller regions. If a ZOFCO is shorter than dim, a cut is placed in the middle of the ZOFCO. If a ZOFCO is longer than dim, cuts are placed to divide the ZOFCO into as many regions of length dim as possible. If the length of a ZOFCO is exactly dim, the ZOFCO is left alone. At a step 308, the method moves the placed cuts to new cut positions in accordance with the layout parameters and the ideal panel size to ensure that the sizes of the panels in the layout are within the ranges set by the user —i.e. that each panel's width is between MinWidth and MaxWidth, etc.—and that the panels'sizes are as close to uniform as possible. The cut adjustment logic is as follows, using vertical cuts as an example; cuts is an array containing the positions of the vertical cuts across a facade:
for i in 1 . . . sizeof(cuts):
   regionWidth=cut[i]−cut[i-1]
   if (regionWidth<MinWidth):
      remove cut to merge with neighboring region
   else if (regionWidth>2*dim):
      add cut that splits region in half
   else if (region>MaxWidth) and (region<2*dim):
      if there's enough wiggle room:
         make the neighboring regions more equal else:
         add cut that splits region in half (3)

This cut adjustment logic is repeated multiple times until the result is acceptable or

can no longer improve. As such, at a next step 310, the method determines whether the positions of any of the cuts across the facade have been changed. If the method determines at a step 310 that a cut position has changed, the method returns to a step 308 to adjust cut positions. If the method determines that the cut position has not changed, the method continues to a step 312. “Wiggle room” refers to the amount by which the size of either the left or right neighboring regions can be increased before they reach MaxWidth (for vertical cuts) or MaxHeight (for horizontal cuts). There's “enough” wiggle room if the total amount of wiggle room is greater than the amount by which the size of the current region exceeds MaxWidth or MaxHeight. If this is the case, the method can “make the neighboring regions more equal” by increasing each neighboring region's size (and, by symmetry, decrease the current region's size) until they've either reached MaxWidth or MaxHeight or have received half of the current region's excess. This “wiggle room” logic—i.e. the portion of the cut adjustment logic starting at the “if there's enough wiggle room” line—is summarized below, again using vertical cuts as an example:
excess=regionWidth−MaxWidth
tol1=MaxWidth−leftRegionWidth
tol2=MaxWidth−rightRegionWidth
if (tol1+tol2>=excess):
   move region's left edge to right by min(tol 1, 0.5*excess)
   move region's right edge to left by min(tol 2, 0.5*excess) else:
   split region in half (4)

After the cuts have been adjusted, the regions between the cuts are examined one

final time to ensure that the number of regions—and thus, the number of panels in the eventual layout—is as small as possible given the provided constraints on panel sizes. The method examines each pair of neighboring regions; if the two regions are in the same ZOFCO—i.e. there isn't a window or door in between them—and their combined size is less than MaxWidth or MaxHeight, the cut separating them is removed, merging the two regions into a single region. As such, at a next step 312, the method determines whether to merge any regions. If the method determines at a step 312 to merge a pair of regions, the method continues to a step 314 to remove a cut between the regions, whereupon the method ends. If the method determines, at a step 312 not to merge any regions, the method ends.

Notably, when horizontal support line positions are specified by the user—i.e. the optional parameter (H) is specified—the method places cuts at those positions first, before any other cuts are placed, and then applies the guillotine operation to each of the horizontal intervals between those cuts individually. This ensures that cuts are placed in a way that prioritizes the support lines properly.

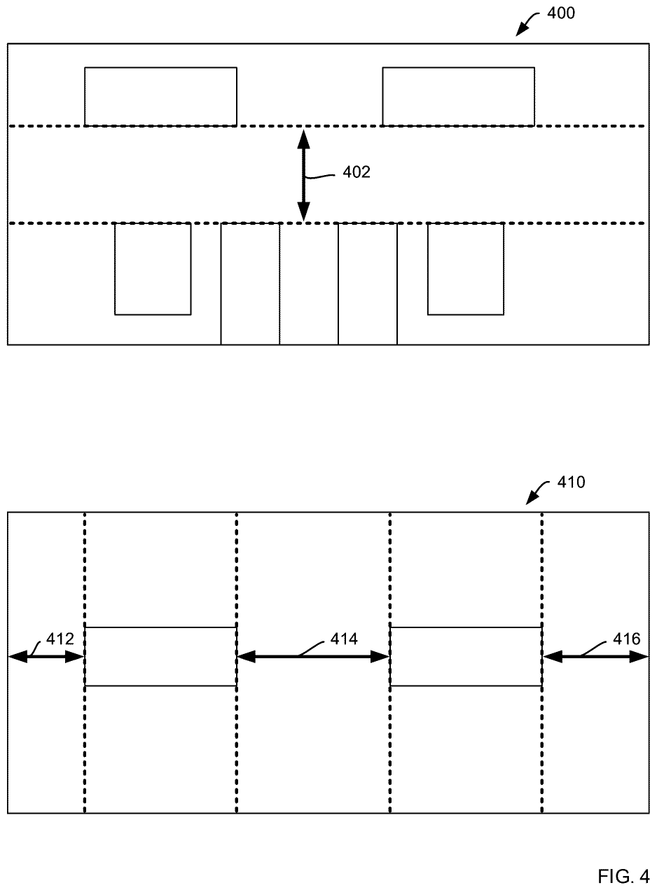

FIG. 4 are illustrative representations of facade regions delineated by guillotine operations in accordance with embodiments of the present invention. As illustrated, facade layout 400 includes horizontal ZOFCO 402 delineated by a horizontal guillotine operation as discussed above. In like manner, facade layout 410 includes vertical ZOFCOS 412, 414, and 416 delineated by a vertical guillotine operation as disclosed above.

FIG. 5 is an illustrative flowchart 500 of window enclosed variant methods for generating panel layouts for building facades in accordance with embodiments of the present invention. In layouts produced by the window enclosed variant, each window or door on the facade is enclosed inside a single panel, and if possible, has even vertical and horizontal padding around it. This variant of the method entails simply running the guillotine operation twice—once to create horizontal cuts, and another time to create vertical cuts—and then intersecting those two sets of cuts to form a panel layout. As such, at a first step 502, the method performs a first guillotine operation to initially divide the building facade into horizontal strips defined by horizontal cuts. Guillotine operation embodiments are disclosed above for FIG. 3. See also facade layout 400, FIG. 4. At a step 504, the method performs a second guillotine operation to divide the building facade into vertical strips defined by vertical cuts. Guillotine operation embodiments are disclosed above for FIG. 3. See also facade 410, FIG. 4. In embodiments, the layout parameters further include a selectively used Delta parameter that defines a minimum acceptable margin between a window edge and a panel edge. As noted above, in the window enclosed variant, if the amount of space between a window or door edge and a facade edge is less than the value of Delta as provided by the user, the method will raise an error. The user can then optionally require the method to automatically ignore the Delta constraint in places where it's physically impossible for the constraint to be satisfied. In addition, if the spacing between a pair of windows or doors is less than the provided value of Delta, the user can optionally require the method to automatically ignore the Delta constraint when there isn't enough space available to enforce it, but can also have the method automatically merge each pair or cluster of window or door cutouts with less-than-Delta space between them into a single large cutout that the method needs to work around. At a step 506, the method intersects the horizontal cuts and the vertical cuts. At a step 508, the method displays the window enclosed variant panel layout, whereupon the method ends. Turning briefly to FIG. 9, FIG. 9 is an illustrative representation of a window enclosed variant panel layout 900 for a building facade in accordance with embodiments of the present invention. As illustrated, window enclosed variant panel layout 900 includes vertical cut 902 and horizontal cut 904 created by methods disclosed herein.

FIG. 6 is an illustrative flowchart 600 of window aligned variant methods for generating panel layouts for building facades in accordance with embodiments of the present invention. In layouts produced by the window aligned variant, each window or door is similarly enclosed inside a single panel, but one of the window or door's edges is precisely aligned with one of the panel's edges. As in the window enclosed variant disclosed above, a guillotine operation is utilized to create horizontal cuts across the facade. To create vertical cuts, each horizontal “strip” of the facade delineated by the guillotine-placed horizontal cuts is processed individually. As such, at a first step 602, the method performs a guillotine operation to initially divide the building facade into horizontal strips defined by horizontal cuts. Guillotine operation embodiments are disclosed above for FIG. 3. See also facade layout 400, FIG. 4. At a step 604, the method creates vertical cuts at the vertical edges of windows and doors. That is, for each horizontal strip containing a door or a window, vertical cuts are created at each of the vertical edges of each of the window outlines and door outlines, such that the horizontal cuts and the vertical cuts define a number of panel regions. At a next step 606, the method determines whether any of the panel regions exceeds MaxWidth. If the method determines at a step 606 that a panel region exceeds MaxWidth, the method continues to a step 608 to divide the panel region, whereupon the method returns to a step 606. In operation, the panel region that's longer than MaxWidth is divided into equal-width regions by additional cuts. Specifically, cuts are placed to divide the region into sub-regions of width dimᵢ, where dimᵢ is calculated using Equations 1 and 2 above from the calculating ideal panel sizes step (see 302, FIG. 3), with(S) set to the width of the region. If the method determines at a step 606 that no panel regions exceed MaxWidth, the method continues to a step 610. At a step 610, for horizontal strips without a window or door, the method causes the horizontal strip to inherit vertical cuts from the nearest horizontal strip that has a window or a door. Specifically, the vertical cut positions are copied from the closest strip either above or below the current strip that contains a window or a door. If there are strips containing windows or doors both above and below the current strip, vertical cut positions are copied from the strip that has fewer vertical cuts. This copying scheme ensures that the aesthetics of the layout remain as consistent as possible between strips; it also helps minimize the number of different panel sizes used in the layout, reducing manufacturing costs.

When horizontal support line positions are specified by the user—i.e. the optional parameter (H) is specified—it's important to minimize the number of horizontal joints in the layout. The number of horizontal joints is minimized when the number of instances in which the two strips directly above and below a support line have different vertical cut positions is minimized. If both of the strips bordering a support line contain windows or doors, the strips'vertical cut positions can't be made the same. However, if only one of the two strips contains a window or a door, the method ensures that the other, window-less strip inherits its vertical cut positions from the strip containing windows or doors. If neither of the two strips contains windows or doors, the method ensures that both strips inherit their vertical cut positions from the same strip. At a step 612, the method displays the window aligned variant panel layout, whereupon the method ends. Turning briefly to FIG. 10, FIG. 10 is an illustrative representation of a window aligned variant panel layout 1000 for a building facade in accordance with embodiments of the present invention. As illustrated, window aligned variant panel layout 1000 includes vertical cut 1002 and horizontal cut 1004 created by methods disclosed herein.

FIG. 7 is an illustrative flowchart 700 of window crossing (MID) sub-variant methods for generating panels for building facades in accordance with embodiments of the present invention. In layouts produced by the window crossing (MID) sub-variant, cuts can bisect windows and doors vertically, precisely at their midpoints, so that each window or door is “framed” by two adjacent panels. Like the window aligned variant, this sub-variant performs a guillotine operation to create horizontal cuts across the facade, and then processes each horizontal “strip” of the facade delineated by those horizontal cuts individually, with window-less strips inheriting their vertical cut positions from strips that contain windows or doors. As such, at a first step 702, the method performs a guillotine operation to initially divide the building facade into horizontal strips defined by horizontal cuts. Guillotine operation embodiments are disclosed above for FIG. 3. See also facade layout 400, FIG. 4. At a step 704, the method creates vertical cuts at the midpoints of windows and doors. That is, for each horizontal strip containing a door or a window, vertical cuts are created at the midpoints of each of the window outlines and door outlines, such that the horizontal cuts and the vertical cuts define a number of panel regions. At a next step 706, the method determines whether any of the panel regions exceeds MaxWidth. If the method determines at a step 706 that a panel region exceeds MaxWidth, the method continues to a step 708 to divide the panel region, whereupon the method returns to a step 706. In operation, the panel region that's longer than MaxWidth is divided into equal-width regions by additional cuts. Specifically, cuts are placed to divide the region into sub-regions of width dimᵢ, where dimᵢ is calculated using Equations 1 and 2 above from the calculating ideal panel sizes step (see 302, FIG. 3), with(S) set to the width of the region. If the method determines at a step 706 that the panel region does not exceed MaxWidth, the method continues to a step 710. At a step 710, for all of the horizontal strips without a window or door, the method causes the horizontal strip to inherit the vertical cuts from the nearest horizontal strip that has a window or a door. Specifically, the vertical cut positions are copied from the closest strip either above or below the current strip that contains a window or a door. If there are strips containing windows or doors both above and below the current strip, vertical cut positions are copied from the strip that has fewer vertical cuts. This copying scheme ensures that the aesthetics of the layout remain as consistent as possible between strips; it also helps minimize the number of different panel sizes used in the layout, reducing manufacturing costs.

When horizontal support line positions are specified by the user—i.e. the optional parameter (H) is specified—it's important to minimize the number of horizontal joints in the layout. This is achieved by minimizing the number of instances where the two strips directly above and below a support line have different vertical cut positions. If both of the strips bordering a support line contain windows or doors, the strips'vertical cut positions can't be made the same. However, if only one of the two strips contains windows or doors, the method ensures that the other, window-less strip inherits its vertical cut positions from the strip containing windows or doors. If neither of the two strips contains windows or doors, the method ensures that both strips inherit their vertical cut positions from the same strip. At a step 712, the method displays the window crossing (MID) sub-variant panel layout, whereupon the method ends. Turning briefly to FIG. 11, FIG. 11 is an illustrative representation of a window crossing (MID) sub-variant panel layout 1100 for a building facade in accordance with embodiments of the present invention. As illustrated, window crossing (MID) sub-variant panel layout 1100 includes vertical cut 1102 and horizontal cut 1104 created by methods disclosed herein.

FIG. 8 is an illustrative flowchart 800 of window crossing (ANY) sub-variant methods for generating panel layouts for building facades in accordance with embodiments of the present invention. In layouts produced by the window crossing (ANY) sub-variant, cuts can bisect windows and doors vertically at any position. The preference is for all cuts to be placed at the midpoints of windows and doors; however, this preference may be relaxed in order to prioritize minimizing the number of different panel sizes used in the layout to reduce manufacturing costs. As such, at a first step 802, the method performs a guillotine operation to initially divide the building facade into horizontal strips defined by horizontal cuts. Guillotine operation embodiments are disclosed above for FIG. 3. See also facade layout 400, FIG. 4. At a step 804, the method creates vertical cuts at the midpoints of the closest pairs of neighboring window or door outlines. In operation, for each strip that contains windows or doors, the method finds the smallest gap between the midpoints of two neighboring window or door outlines in the strip and places initial vertical cuts at those two outlines'midpoints. The method places similar vertical cuts at the midpoints of every other pair of neighboring window or door outlines that have a midpoint gap of that same smallest size. At a step 806, the method divides panel regions vertically to a user selected width. In operation, the method calculates the region width dimₛ that would allow dividing each of the midpoint gaps into equal-width regions using Equations 1 and 2 above from the calculating ideal panel sizes step (see 302, FIG. 3), with(S) set to the gap width, and places cuts dividing each of the gaps into dimₛ-width regions. With the strip now divided into regions by those first vertical cuts, the method then divides all of the regions that are wider than dimₛ into dims-width sub-regions. In order for this variant to produce a sensible panel layout, MinWidth cannot be larger than the width of the smallest gap between the midpoints of two neighboring windows.

The method continues to steps 808 to 814 to adjust the vertical cuts so that the regions delineated by those cuts are all between MinWidth and MaxWidth. While dimₛ is guaranteed to be at most MaxWidth, the placement of cuts at intervals of dimₛ does not guarantee that the widths of all of the regions of the strip are at least MinWidth. To do this, the method first examines each pair of neighboring cuts, removing the cut on the left of each panel region whose width is less than MinWidth. The last cut is treated as the left edge of a region that ends at the right boundary of the facade. As such, at a step 808, the method determines whether any of the panel regions delineated by the vertical cuts are smaller than MinWidth. If the method determines at a step 808 that a panel region is smaller than MinWidth, the method continues to a step 810 to adjust the vertical cuts delineating the panel region by removing the cut on the left of the panel region, whereupon the method returns to a step 808. If the method determines at a step 808 that no panel regions are smaller than MinWidth, the method continues to a step 812. Next, the method ensures that the adjusted panel regions are of width at most MaxWidth. To do this, the method examines each pair of neighboring cuts, shifting the cut on the right of each region whose width is greater than MaxWidth to the left until the width of the region is exactly MaxWidth. The first cut is treated as the right edge of a region starting at the left boundary of the facade. As such, at a step 812, the method determines whether any of the panel regions delineated by the vertical cuts are wider than MaxWidth. If the method determines at a step 812 that a panel region is greater than MaxWidth, the method continues to a step 814 to adjust the vertical cuts delineating the panel region by shifting the cut on the right of the panel region to the left until the width of the region is exactly MaxWidth, whereupon the method returns to a step 812. If the method determines at a step 812 that no panel regions are wider than MaxWidth, the method continues to a step 816.

During this second round of adjustment, a new region between the last cut and the right facade boundary that is wider than MaxWidth may be introduced. If necessary, the method places cuts to divide this final region into equal-width sub-regions, calculating the sub-region width using Equations 1 and 2 above from the calculating ideal panel sizes step (see 302, FIG. 3). As such, at a step 816, the method determines whether the rightmost panel region is wider than MaxWidth. If the method determines at a step 816, that the rightmost panel region is wider than MaxWidth, the method continues to a step 818 to divide the panel region. If the method determines at a step 816, that the rightmost panel region is not wider than MaxWidth, the method continues to a step 820 to display the window crossing (ANY) sub-variant panel layout, whereupon the method ends. Turning briefly to FIG. 12, FIG. 12 is an illustrative representation of a window crossing (ANY) sub-variant panel layout 1200 for a building facade in accordance with embodiments of the present invention. As illustrated, window crossing (ANY) sub-variant panel layout 1200 includes vertical cut 1202 and horizontal cut 1204 created by methods disclosed herein.

### Conflict Detection

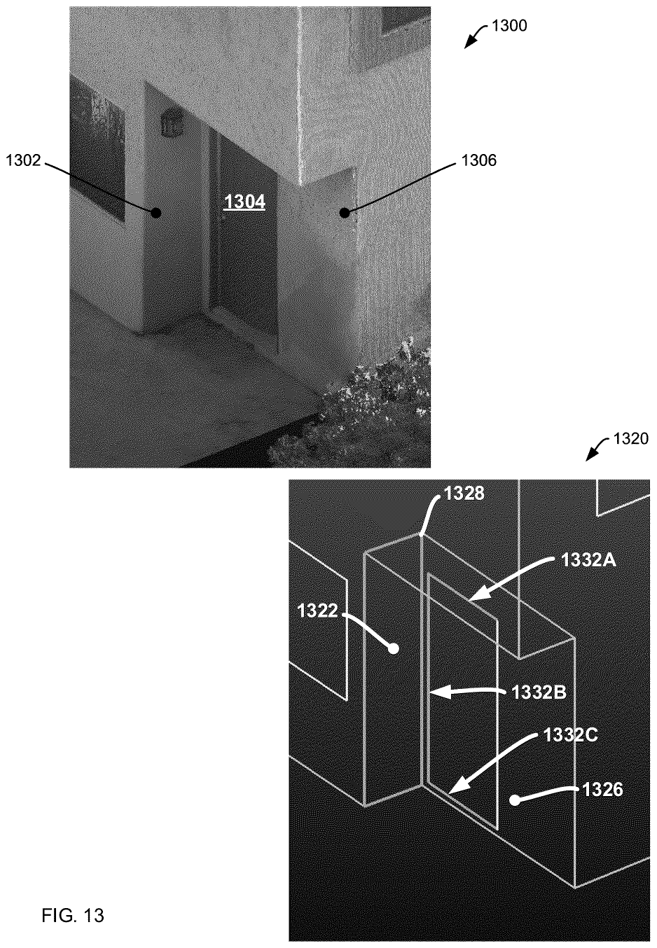

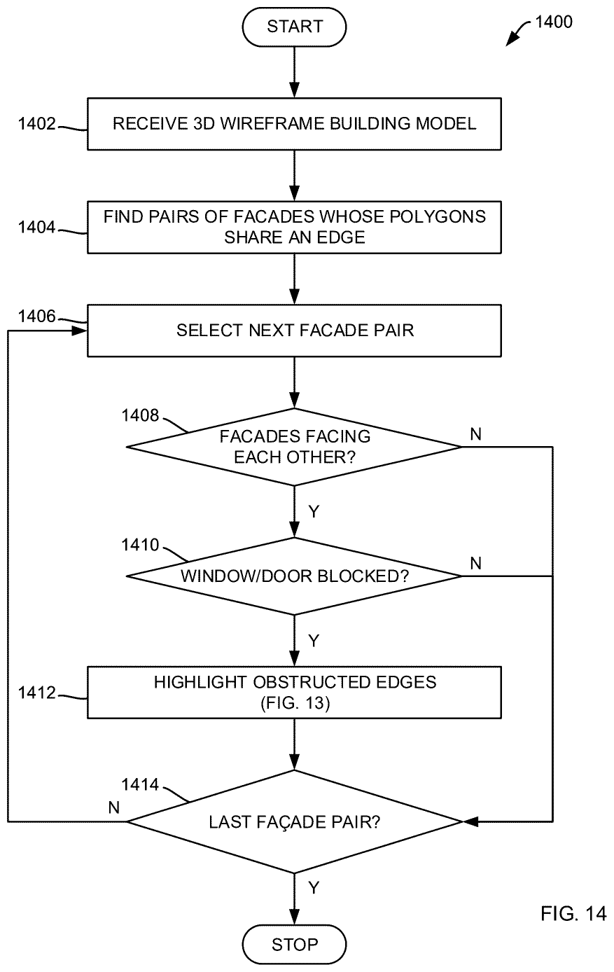

Since insulation panels are typically several inches thick, when the panels are mounted on a building's facades, each facade may protrude outward several more inches than it formerly did. This can cause issues when two facades are perpendicular to each other; windows and doors close to facade edges may be partially obstructed by panels mounted on facades that are perpendicular to those edges. As such, blockage of a door (or window) by a panel is referred to as a “conflict” herein. For example, turning to FIG. 13, FIG. 13 is an illustrative representation of a pair of facades that have a conflict in accordance with embodiments of the present invention. As illustrated, building portion 1300 illustrates that a panel installed on facade 1302 may block part of door 1304 on facade 1306.

FIG. 14 is an illustrative flowchart 1400 of conflict finding methods for generating panels for building facades in accordance with embodiments of the present invention. At a first step 1402, the method receives a 3D wireframe building model. Technically, this model is provided as a set of facades, each of which has an associated polygon, an associated set of window and door outlines, and an associated normal vector—i.e. a vector perpendicular to the facade that points outwards from the exterior facade surface. At a next step 1404, the method finds pairs of facades whose polygons share an edge. For each facade (F), the method examines every other facade (Fᵢ) and determines whether (Fᵢ) shares a facade edge with (F)—i.e. whether one of the edges in the (Fᵢ) polygon exactly matches one of the edges in the (F) polygon. Turning briefly to FIG. 13, illustrated is wireframe model 1320 representing building portion 1300. As illustrated, facades 1322 and 1326 share edge 1328. Once all of the facade pairs that share an edge are found, the method individually examines each facade pair. As such, at a step 1406, the method selects a next facade pair. The method continues to a step 1408 to determine whether the facades (F₁) and (F₂) that constitute the pair are facing each other. If (F₁) and (F₂) are both facing each other, panels placed on (F₂) could block parts of (F₁). The method finds the centers of both the (F₁) polygon and the (F₂) polygon—by simply averaging the X-, Y-, and Z-coordinates of the polygons'vertices—and then calculates the midpoint (M) of the line connecting those two polygon centers. Next, the method calculates the vector between (M) and the center of the (F₁) polygon and computes the dot product of this vector and the (F₁) normal vector. It performs the same dot product computation for (F₂). If both of those two dot products are positive, then the two facades face each other. As such, if the method determines at a step 1408 that the two facades are facing each other, the method continues to a step 1410. If the method determines at a step 1408 that the two facades are not facing each other, the method continues to a step 1414.

At a next step 1410, the method determines whether the window or door is blocked. In operation, the method examines every edge of every window and door on (F₁). For each of those window and door edges (Eⱼ), the method finds the infinite-extent line that contains the straight facade edge shared by (F₁) and (F₂), and then finds the closest points (P_{j,0}) and (P_{j,1}) on that infinite-extent line to the endpoints (E_{j,0}) and (E_{j,1}) of (Eⱼ). If either (P_{j,0}) or (P_{j,1}) falls between the endpoints of the shared facade edge, then at least part of the edge falls in the region of (F₁) that could be obstructed by panels mounted on (F₂). To determine if (Eⱼ) will be partially or fully obstructed, the method determines whether (Eⱼ) is within (T) inches of the shared facade edge, where (T) is the panel thickness specified by the user. Specifically, the method computes the distance from (E_{j,0}) to (P_{j,0}) and the distance from (E_{j,1}) to (P_{j,1}). If either of those distances are less than (T), then panels mounted on (F₂) will block part of (Eⱼ). If the method determines at a step 1410 that the window or door is blocked, the method continues to a step 1412 to highlight the obstructing facade and the obstructed edges. That is, the method highlights both (Eⱼ) and (F₂) in the wireframe building model. Returning again briefly to FIG. 13, facade 1322 and edges-32A-1332C of wireframe model 1320 are highlighted. If the method determines at a step 1410 that the window or door is not blocked, the method continues to a step 1414.

At a step 1414, the method determines whether the last facade pair has been examined. If the method determines at a step 1414 that the last facade pair has not been examined, the method returns to a step 1406. If the method determines at a step 1414 that the last facade pair has been examined, the method ends.

The terms “certain embodiments”, “an embodiment”, “embodiment”, “embodiments”, “the embodiment”, “the embodiments”, “one or more embodiments”, “some embodiments”, and “one embodiment” mean one or more (but not all) embodiments unless expressly specified otherwise. The terms “including”, “comprising”, “having” and variations thereof mean “including but not limited to”, unless expressly specified otherwise. The enumerated listing of items does not imply that any or all of the items are mutually exclusive, unless expressly specified otherwise. The terms “a”, “an” and “the” mean “one or more”, unless expressly specified otherwise.

While this invention has been described in terms of several embodiments, there are alterations, permutations, and equivalents, which fall within the scope of this invention. It should also be noted that there are many alternative ways of implementing the methods and apparatuses of the present invention. Furthermore, unless explicitly stated, any method embodiments described herein are not constrained to a particular order or sequence. Further, the Abstract is provided herein for convenience and should not be employed to construe or limit the overall invention, which is expressed in the claims. It is therefore intended that the following appended claims be interpreted as including all such alterations, permutations, and equivalents as fall within the true spirit and scope of the present invention.

What is claimed is:

1. A method for generating panel layouts for building facades comprising:
receiving a 2D facade polygon, wherein the 2D facade polygon represents an outline of a building facade;
receiving a set of 2D fenestration polygons, wherein the set of 2D fenestration polygons represent a plurality of window outlines and a plurality of door outlines corresponding with the building facade; and
determining a panel layout for the building facade.

2. The method of claim 1, wherein the determining a panel layout for the building facade comprises:
inputting layout parameters;
performing a first guillotine operation to initially divide the building facade into horizontal strips defined by a plurality of horizontal cuts;
creating the panel layout selected from the group consisting of: a window enclosed layout, a window aligned layout, a window crossing (MID) layout, and a window crossing (ANY) layout;
and optionally returning to the inputting layout parameters.

3. The method of claim 2, wherein the guillotine operation comprises:
calculating an ideal panel size for the building facade;
finding one or more zones free of conflict (ZOFCOS);
placing a plurality of cuts to divide the one or more ZOFCOS;
adjusting the plurality of cuts to new cut positions in accordance with the layout parameters and the ideal panel size; and
continuing the adjusting the plurality of cuts until the new cut positions do not change.

4. The method of claim 3, further comprising:
optionally removing one of the plurality of cuts to merge neighboring regions separated by the one of the plurality of cuts in accordance with the layout parameters.

5. The method of claim 2, wherein the layout parameters comprise at least some of:
a minimum acceptable width of a panel;
a maximum acceptable width of a panel;
a minimum acceptable height of a panel;
a maximum acceptable height of a panel;
a minimum acceptable margin between a window edge and a panel edge;
a real number whose value represents a position of a horizontal support line.

6. The method of claim 5, wherein the creating the window enclosed layout comprises:
performing a second guillotine operation to initially divide the building facade into vertical strips defined by a plurality of vertical cuts, wherein the layout parameters further include a selectively enforced Delta parameter, the selectively enforced Delta parameter defining the minimum acceptable margin between a window edge and a panel edge;
intersecting the plurality of horizontal cuts and the plurality of vertical cuts; and
displaying the window enclosed layout.

7. The method of claim 6, wherein
if a space between a pair of window or door cutouts is less than the selectively enforced Delta parameter, ignoring the selectively enforced Delta parameter; or
merging each pair of window or door cutouts with the space between the pair of window or door cutouts into a single merged cutout.

8. The method of claim 5, wherein the creating the window aligned layout comprises:
for a first horizontal strip having a door or a window, creating a plurality of vertical cuts at vertical edges of the plurality of window outlines and the plurality of door outlines, wherein the plurality of horizontal cuts and the plurality of vertical cuts define a plurality of panel regions;
dividing any panel region that is greater than the maximum acceptable width of a panel;
for a second horizontal strip not having a door or window, inheriting the plurality of vertical cuts from a nearest horizontal strip having the door or the window; and
displaying the window aligned layout.

9. The method of claim 5, wherein the creating the window crossing (MID) layout comprises:
for a first horizontal strip having a door or a window, creating a plurality of vertical cuts at midpoints of the plurality of window outlines and the plurality of door outlines, wherein the plurality of horizontal cuts and the plurality of vertical cuts define a plurality of panel regions;
dividing any panel region that is greater than the maximum acceptable width of a panel;
for a second horizontal strip not having a door or window, inheriting the plurality of vertical cuts from a nearest horizontal strip having the door or the window; and
displaying the window crossing (MID) layout.

10. The method of claim 5, wherein the creating the window crossing (ANY) layout comprises:
for a first horizontal strip having a window, creating a plurality of vertical cuts at midpoints of closest pairs of neighboring windows;
further dividing the first horizontal strip having the window to a user selected width;
adjusting any vertical cut of any panel region that is less than the minimum acceptable width of a panel;
adjusting any vertical cut of any panel region that is greater than the maximum acceptable width of a panel;
dividing a rightmost panel region that is greater than the maximum acceptable width of the panel; and
displaying the window crossing (ANY) layout.

11. The method of claim 2, wherein the set of 2D fenestration polygons is empty.
